(19) United States
(12) Patent Application Publication
(10) Pub. No.: US 2023/0231042 A1
(43) Pub. Date: Jul. 20, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Makoto KOSHIMIZU, Tokyo (JP); Yasutaka NAKASHIBA, Tokyo (JP); Hitoshi MATSUURA, Tokyo (JP)

(21) Appl. No.: 18/055,635

(22) Filed: Nov. 15, 2022

(30) Foreign Application Priority Data
Jan. 17, 2022 (JP) 2022-004758

(51) Int. Cl. H01L 29/739; H01L 29/06; H01L 29/861; H01L 29/66

(52) U.S. Cl. CPC H01L 29/7397; H01L 29/0657; H01L 29/861; H01L 29/66348

(57) ABSTRACT

A reliability of a semiconductor device is ensured, and performance of the device is improved. A semiconductor device including a region 1A and a region 2A includes an n-type semiconductor substrate TS having a front surface BS1, BS2 and a back surface SUB, a IGBT formed on a semiconductor substrate in a region 1A, and a diode formed on the semiconductor substrate SUB in a region 2A. And a thickness T1 of the semiconductor substrate SUB in the region 1A is smaller than a thickness of the semiconductor substrate T2 in the region 2A.

### CROSS-REFERENCE TO RELATED APPLICATIONS

The disclosure of Japanese Patent Application No. 2022-004758 filed on Jan. 17, 2022, including the specification, drawings and abstract is incorporated herein by reference in its entirety.

### BACKGROUND OF THE INVENTION

The present disclosure relates to a semiconductor device and a method of manufacturing the same, and more particularly, to a semiconductor device including a IGBT and a method of manufacturing the same.

A trench gate type IGBT (Insulated Gate Bipolar Transistor) having a low on-resistance is widely used. Further, a semiconductor module including a semiconductor chip on which a IGBT is formed and a semiconductor chip on which a freewheeling diode is formed is used in a power converter or the like for controlling a motor. The freewheeling diode is connected in anti-parallel to IGBT and repeats the operation in which one is in the on-state and the other is in the off-state.

For example, Japanese unexamined Patent Application publication 2017-011000 discloses an inverse conduction type IGBT (RC-IGBT) configured by connecting a freewheeling diode to a IGBT in anti-parallel. IGBT and the freewheeling diode are formed on the same semiconductor board and incorporated in one semiconductor chip. By using such a RC-IGBT, it is possible to reduce the size of the power converter.

### SUMMARY OF THE INVENTION

The present inventors have studied a semiconductor device (semiconductor chip) including a RC-IGBT. As a result, it was found that, although the on-resistance can be reduced by reducing the thickness of the semiconductor substrate, ringing easily occurs at the time of turn-off. For example, when the thickness of the semiconductor substrate is sufficiently large, holes are re-injected from the p-type collector region formed on the back surface side of the semiconductor substrate. As a result, carriers remain even at the end of turn-off, and the electric field on the back surface side is relaxed, so that ringing does not occur. If the thickness of the semiconductor substrate is too thin, punch-through occurs at the end of turn-off. At this time, since the thickness of the depletion layer is fluctuated, when the thickness of the depletion layer becomes approximately the same as the thickness of the semiconductor substrate, carriers are depleted on the back surface side, a high electric field is generated, ringing occurs.

On the other hand, in the diode, an n-type cathode region is formed on the back surface side of the semiconductor substrate, and since there is no supply of holes from the back surface side, the depletion layer spreads from both the front surface side and the back surface side. Here, if the thickness of the semiconductor substrate is too thin, the depletion layer from the front surface side and the depletion layer from the back surface side are connected, punch-through occurs, ringing occurs. When IGBT and the diode are formed on the same semiconductor substrate and the thicknesses of the semiconductor substrates in the respective regions are the same, the diode is more likely to cause ringing.

Therefore, in view of the reliability of RC-IGBT, the thickness of the semiconductor-substrate needs to be set in accordance with the characteristics of the diode in order to suppress ringing. That is, it is necessary to increase the thickness of the semiconductor substrate to such an extent that no ringing occurs in the diode. However, in IGBT, since the thickness of the semiconductor-substrate is unnecessarily increased, the on-resistance is increased. In other words, when the reliability of the semiconductor device is prioritized, the performance of the semiconductor device deteriorates.

Therefore, it is desired to develop a technique capable of suppressing ringing in both IGBT and the diode and reducing the on-resistance of IGBT. That is, it is desired to develop a technique for securing the reliability of the semiconductor device and improving the performance of the semiconductor device.

Other objects and novel features will become apparent from the description of this specification and the accompanying drawings.

The typical ones of the embodiments disclosed in the present application will be briefly described as follows.

A semiconductor device according to an embodiment includes a first region and a second region. Further, the semiconductor device includes a semiconductor substrate of a first conductivity type having a front surface and a back surface, a IGBT formed on the semiconductor substrate of the first region, and a diode formed on the semiconductor substrate of the second region. Here, a thickness of the semiconductor substrate in the first region is smaller than a thickness of the semiconductor substrate in the second region.

A method of manufacturing a semiconductor device including a first region and a second region according to an embodiment includes the steps of: (a) preparing a semiconductor substrate of a first conductivity type having a front surface and a back surface; (b) forming a IGBT on the semiconductor substrate of the first region, and forming a diode on the semiconductor substrate of the second region; (c) making a thickness of the semiconductor substrate of the first region thinner than a thickness of the semiconductor substrate of the second region.

According to the embodiment, the reliability of the semiconductor device can be secured, and the performance of the semiconductor device can be improved.

### BRIEF DESCRIPTION OF THE DRAWINGS

FIG. 1 is a plan view showing a semiconductor device according to the first embodiment.

FIG. 2 is a plan view showing a semiconductor device according to the first embodiment.

FIG. 3 is a plan view showing a semiconductor device according to the first embodiment.

FIG. 4 is a perspective view showing a semiconductor device according to the first embodiment.

FIG. 5 is a sectional view showing a semiconductor device according to the first embodiment.

FIG. 6 is a schematic diagram showing a state of the etching process using an etching solution containing TMAH.

FIG. 7 is a plan view showing a semiconductor substrate in a wafer state according to the first embodiment.

FIG. 8 is a cross-sectional view showing a manufacturing process of a semiconductor device according to the first embodiment.

FIG. 9 is a cross-sectional view illustrating a manufacturing step following FIG. 8.

FIG. 10 is a cross-sectional view illustrating a manufacturing step following FIG. 9.

FIG. 11 is a cross-sectional view illustrating a manufacturing step following FIG. 10.

FIG. 12 is a cross-sectional view illustrating a manufacturing process following FIG. 11.

FIG. 13 is a cross-sectional view illustrating a manufacturing process following FIG. 12.

FIG. 14 is a cross-sectional view illustrating a manufacturing process following FIG. 13.

FIG. 15 is a sectional view showing a semiconductor device according to a second embodiment.

FIG. 16 is a cross-sectional view illustrating a manufacturing process of a semiconductor device according to the second embodiment.

FIG. 17 is a sectional view showing a semiconductor device according to a third embodiment.

FIG. 18 is a plan view showing a semiconductor device according to a fourth embodiment.

FIG. 19 is a plan view showing a semiconductor device according to the fourth embodiment.

FIG. 20 is a plan view showing a manufacturing process of the opening in a fifth embodiment.

FIG. 21 is a plan view showing a semiconductor device according to the fifth embodiment of the present invention.

### DETAILED DESCRIPTION

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a height direction, or a thickness direction of a certain structure. In addition, expressions such as “plan view” or “plan view” used in the present application mean that a surface constituted by the X direction and the Y direction is referred to as a “plane”, and the “plane” is viewed from the Z direction.

In addition, in the present application, when a numerical range such as “1 to 10 μm” is expressed, it means “1 μm or more and 10 μm or less”. The same applies to other numerical values and other units.

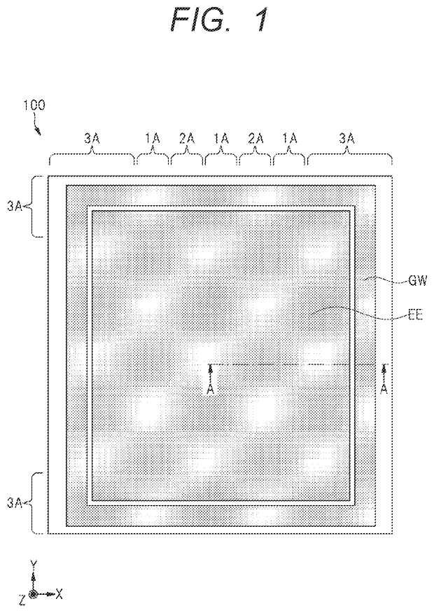

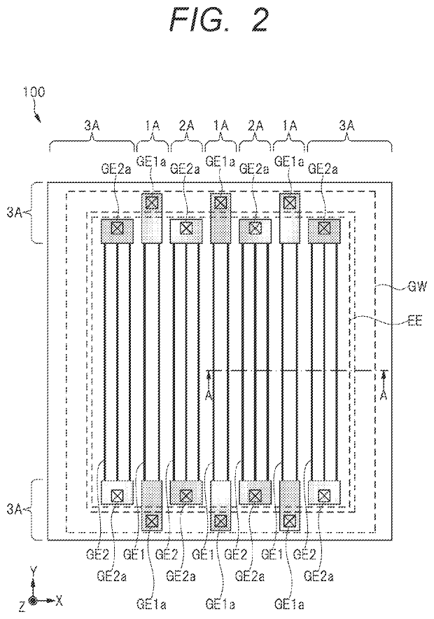

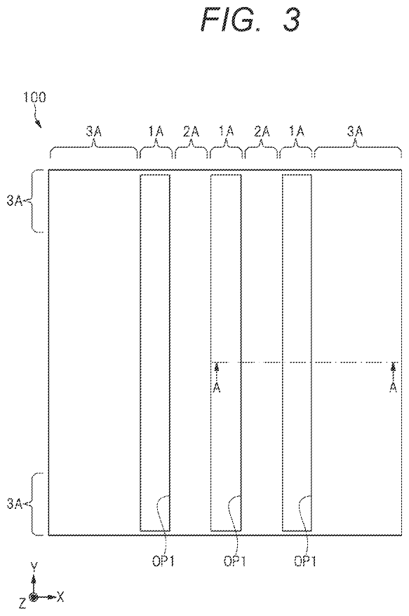

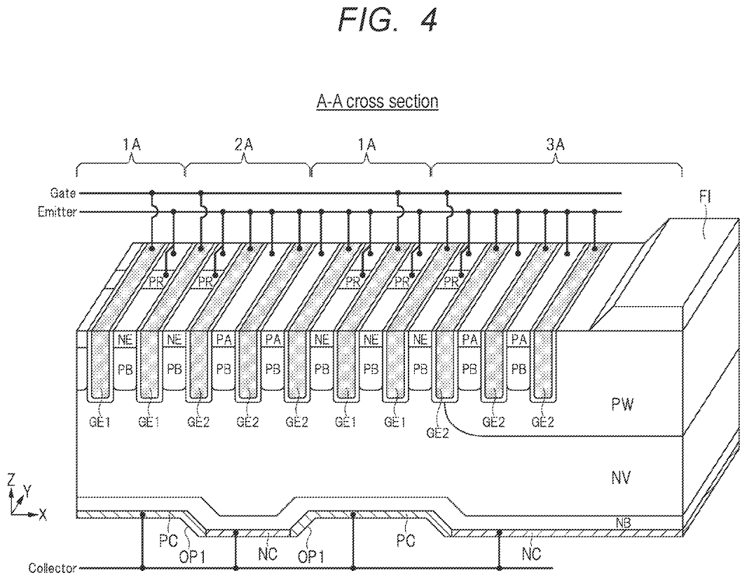

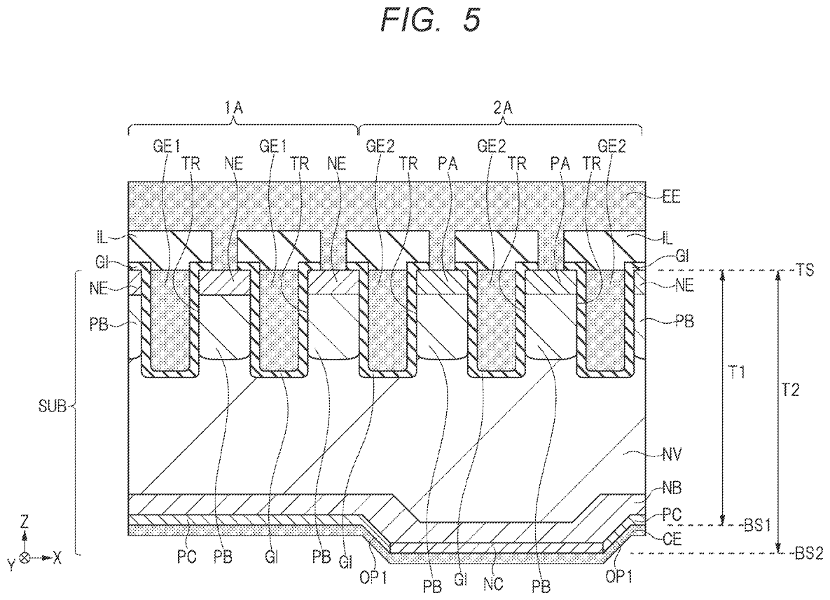

A semiconductor device 100 according to Embodiment 1 will be described below with reference to FIGS. 1 to 5. FIG. 1 to FIG. 3 are plan views illustrating a semiconductor chip that is a semiconductor device 100. FIG. 1 mainly shows a wiring layer. FIG. 2 is a diagram illustrating a configuration mainly in the vicinity of the front surface TS of SUB. FIG. 3 illustrates a back surface BS of the semiconductor-substrate SUB. FIG. 4 is a perspective view based on a cross section along A-A shown in FIGS. 1-3. FIG. 5 is an enlarged cross-sectional view of the region 1A and the area 2A shown in FIG. 4.

The semiconductor device 100 includes a region 1A in which a semiconductor element such as a IGBT is formed, a region 2A in which a semiconductor element such as a diode is formed, and an outer peripheral region 3A surrounding the region 1A and the region 2A in plan view. The semiconductor device 100 constitutes a RC-IGBT and can be used as a power converter or the like for controlling a motor.

The semiconductor-substrate SUB has a front-side TS and a back surface BS. The main feature of the present application is that the thickness of the semiconductor substrate SUB of the region 1A is smaller than the thickness of the semiconductor substrate SUB of the region 2A. According to the embodiments or the respective manufacturing processes, the front surface 1A and the back surface TS of the region BS may be referred to as a front surface TS1 and a back surface BS1, and the front surface TS and the back surface BS of the area 2A may be referred to as a front surface TS2 and a back surface BS1.

As shown in FIG. 1, most of the device 100 is covered with an emitter-electrode EE. A gate-line GW is formed on the outer periphery of the emitter-electrode EE. Part of each of the emitter-electrode EE and the gate-line GW is covered with a protective film (not shown). A region exposed from the protective film is an emitter pad and a gate pad. External connection terminals such as wire bonding or clips (copper plates) are connected to the emitter pad and the gate pad, so that the semiconductor device 100 is electrically connected to another semiconductor chip, a wiring board, or the like.

As shown in FIGS. 4 and 5, the semiconductor device 100 includes a semiconductor board SUB having a low-concentration n-type drift-region NV. Here, the n-type semiconductor-substrate SUB itself constitute the drift-region NV. Note that the drift-region NV may be a stack of an n-type silicon substrate and semiconducting layers grown by introducing phosphorus (P) onto the silicon substrate by epitaxial growth. In the present application, such a stack is also described as being a semiconductor-substrate SUB. The doping density of the drift-region NV is 1×10¹³˜2×10¹⁴ cm⁻³.

On SUB of the semiconductor substrate TS of the semiconductor substrate 1A and the region 2A, a plurality of trench TR are formed. The bottom of the trench TR is located below the base-region PB described later. A gate insulating film GI is formed inside the trench TR. The gate electrode GE1 is formed on the gate insulating film GI so as to fill the inside of the trench TR in the regions 1A. The gate electrode GE2 is formed on the gate insulating film GI so as to fill the inside of the trench TR in the regions 2A. The gate-insulating film GI is made of, for example, a silicon-oxide film, and has, for example, 50˜100 nm thickness. The gate-electrode GE1, GE2 is formed of, for example, an n-type doped polycrystalline silicon film.

On the front-side SUB of the semiconductor substrate TS, in the semiconductor substrate SUB of the region 1A and the region 2A, a p-type base region (semiconductor region) PB is formed. In the base region PB of the region 1A, an n-type emitter region (semiconductor region) NE is formed. A p-type anode-region (semiconductor-region) PA is formed in the base-region PB of the region 2A. As shown in FIG. 4, a p-type high-concentration diffused region (semiconducting region) PR is formed in a part of the base region PB of the region 1A. In the region 1A, the emitter potential is supplied to the base region PB via the high-concentration diffused region PR.

The impurity concentration of the base-region PB is 1×10¹⁶˜1×10¹⁸ cm⁻³. The impurity concentration of the emitter region NE is higher than the impurity concentration of the drift region NV and is 1×10¹⁸˜1×10²¹ cm⁻³. The impurity concentration of the anode region PA is higher than the impurity concentration of the base region PB and is 1×10¹⁸˜1×10²¹ cm⁻³. The impurity concentration of the high-concentration diffused region PR is higher than the impurity concentration of the base region PB and is 1×10¹⁸˜1×10²¹ cm⁻³.

Further, as shown in FIG. 4, on the semiconductor substrate SUB on the front TS of the semiconductor substrate SUB, a p-type well region (semiconductor region) PW is formed on the semiconductor substrate 3A in the outer peripheral region 3A, and a field-insulating film FI is formed on the semiconductor substrate PW in the outer peripheral region. The well area PW is formed to a position deeper than the bottom of the trench TR. The impurity concentration of the well region PW is lower than the impurity concentration of the base region PB and is 1×10¹⁵˜1×10¹⁷ cm⁻³. The field-insulating film FI is made of, for example, a silicon-oxide film, and has, for example, 600˜1000 nm thickness.

An interlayer insulating film IL is formed on the front surface TS of the semiconductor-substrate SUB in the region 1A˜3A. A contact hole is formed in the interlayer insulating film IL. An emitter-electrode EE is formed on the interlayer insulating film IL so as to fill the inside of the contact hole. The emitter electrode EE is electrically connected to the emitter region NE, the anode region PA, the base region PB, and the highly diffused region PR, and supplies an emitter potential to these regions.

Although not illustrated here, a gate-wiring GW formed in the same process as that of the emitter-electrode EE is also formed on the interlayer insulating film IL. The emitter-electrode EE and the gate-line GW include, for example, a titanium nitride film and an aluminum film formed on the titanium nitride film. The aluminum film is a main conductive film of the emitter-electrode EE and the gate-line GW, and is sufficiently thicker than the titanium-nitride film.

As shown in FIG. 2, in the first embodiment, the plurality of gate-electrodes GE1, GE2 extend in the Y-direction and adjoin each other in the X-direction. That is, the plurality of trenches TR extend in the Y direction, respectively, and adjoin each other in the X direction. In the outer peripheral region 3A, the plurality of gate electrodes GE1 are connected to the gate lead-out portion GE1a, and the gate lead-out portion GE1a is electrically connected to the gate wire GW via a contact hole formed in the interlayer insulating film IL. Therefore, the gate potential is supplied to the gate electrode GE1 from the gate line GW.

Further, in the outer peripheral region 3A, the plurality of gate electrodes GE2 are connected to the gate lead-out portion GE2a, and the gate lead-out portion GE2a is electrically connected to the emitter electrode EE via a contact hole formed in the interlayer insulating film IL. Therefore, the emitter potential is supplied from the emitter electrode EE to the gate electrode GE2.

Note that the gate lead-out portion GE1a, GE2a is formed of a polycrystalline silicon film having a pattern larger than that of the gate electrode GE1, GE2 and buried inside the trench TR via the gate insulating film GI.

On the back surface BS of the semiconductor substrate SUB, an n-type buffer region (semiconductor region) NB is formed on the back surface BS of the semiconductor substrate 1A˜3A. The buffer region NB is provided to prevent the depletion layer extending from pn junction TS the front surface of SUB from reaching the p-type collector region PC when IGBT is turned off. The impurity concentration of the buffer region NB is higher than the impurity concentration of the drift region NV and is 5×10¹⁶˜5×10¹⁷ cm⁻³.

On the back surface BS of the semiconductor substrate SUB, an n-type cathode region (semiconductor region) NC is formed on the back surface BS of the region 1A on the back surface SUB of the semiconductor substrate BS, and a p-type collector region (semiconductor region) PC is formed on the back surface 2A and the semiconductor substrate SUB on the outer peripheral region 3A. The collector region PC and the cathode region NC are located below the buffer region NB. The impurity concentration of the collector-region PC is 1×10¹⁷˜1×10²¹ cm⁻³. The impurity concentration of the cathode region NC is higher than the impurity concentration of the drift region NV and is 1×10¹⁸˜1×10²¹ cm⁻³.

A collector-electrode CE is formed on the back surface BS of the region 1A on SUB. The collector electrode CE is electrically connected to the collector region PC and the cathode region NC, and supplies a collector potential to these regions. The collector-electrode CE is formed of, for example, a laminated film including a nickel silicide film and a metallic film such as a titanium film, a nickel film, and a gold film sequentially formed on the nickel silicide film.

In Embodiment 1, as shown in FIGS. 3 to 5, an opening OP1 is formed on the back surface BS of the region 1A on SUB of the semiconductor-substrate. Therefore, so that the back surface BS1 of the semiconductor substrate SUB of the region 1A is positioned above the back surface BS2 of the semiconductor substrate SUB of the region 2A, a step is generated on the back surface BS of the semiconductor substrate SUB. That is, the thickness T1 of the semiconductor substrate SUB in the region 1A is smaller than the thickness T2 of the semiconductor substrate SUB in the region 2A.

As illustrated in FIG. 5, the thickness 1A of the semiconductor substrate SUB in the region T1 is a thickness from the front surface TS of the semiconductor substrate SUB to the back surface BS1 of the semiconductor substrate OOF. The thickness 2A of the semiconductor substrate SUB in the region T2 is the thickness of the semiconductor substrate SUB from the front surface TS to the back surface BS2 of the semiconductor substrate SUB. The thickness T1 and the thickness T2 are set to, for example, 50 to 160 μm, but the thickness T1 is thinner than the thickness T2 in the range of 1 to 10 μm. More preferably, the thickness T2 is 85 μm and the thickness T1 is 5 μm thinner than the thickness T2.

Therefore, the distance between the base region PB of the region 1A and the collector region PC of the region 1A is shorter than the distance between the base region PB of the region 2A and the cathode region NC of the region 2A. In other words, the thickness of the drift region NV of the region 1A is smaller than the thickness of the drift region NV of the region 2A.

As described above, when the thickness of the semiconductor substrate SUB in the region 1A in which IGBT is formed is the same as the thickness of the semiconductor substrate SUB in the region 2A in which the diode is formed, the possibility of ringing is larger for the diode. Therefore, in view of the reliability of RC-IGBT, in order to suppress the ringing in the region 2A, the thickness of the semiconductor-substrate SUB of the region 2A needs to be increased. As a result, the thickness of the semiconductor-substrate SUB in the region 1A is also increased. Therefore, the on-resistance of IGBT is increased.

In the first embodiment, since the thickness of the semiconductor-substrate SUB is changed, ringing can be suppressed in the region 2A, and on-resistance can be reduced in the region 1A. That is, the reliability of the semiconductor device can be ensured, and the performance of the semiconductor device can be improved.

In the first embodiment, the thickness of the semiconductor-substrate SUB in the outer peripheral region 3A is the same thickness T2 as the region 2A. That is, the thickness T1 of the semiconductor substrate SUB in the region 1A is smaller than the thickness T2 of the semiconductor substrate 3A in the outer peripheral region 1A. Therefore, in the outer peripheral region 3A, as in the area 2A, ringing can be suppressed, and the breakdown voltage can be easily secured. In addition, since the n-type cathode region NC is also formed on the back surface BS2 of the semiconductor substrate SUB in the outer peripheral region 3A, excessive holes are injected less, so that the breakdown voltage and the breakdown resistance are easily secured.

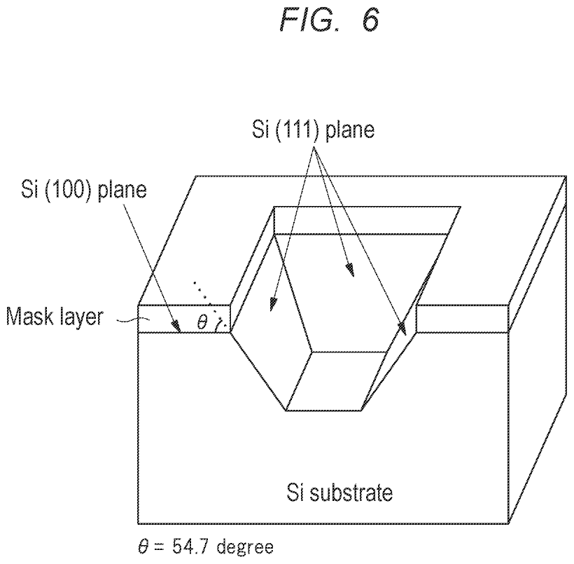

A method of forming an opening OP1, i.e., a method of changing the thickness of a semiconductor-substrate SUB, will be described below with reference to FIG. 6. In the first embodiment, an etching process using an etching solution containing tetramethylammonium hydroxide (TMAH) is performed to form an opening OP1.

FIG. 6 is a view illustrating a state in which an etching process is performed on a silicon-based semiconductor-substrate using an etching solution containing TMAH. The crystal plane of the surface of the semiconductor substrate is a (100) plane.

A mask layer such as a resist pattern or a silicon oxide film is selectively formed on the semiconductor substrate, and an etching process using an etching solution containing TMAH is performed using the mask layer as a mask. As a result, a groove is formed in the semiconductor substrate. After a certain period of time, all of the crystal planes on the side surface of the groove become (111) planes, and the side surface of the groove becomes flat planes. The angle θ formed between the surface of the semiconductor substrate and the side surface of the groove is 54.7 degrees.

The semiconductor-substrate SUB of the first embodiment has the same configuration as that of FIG. 6. That is, the crystal plane on the front surface TS of the semiconductor-substrate SUB is the (100) plane, and the crystal plane on the side surface of the opening OP1 is the (111) plane. The angle θ formed between the front surface TS of the semiconductor-substrate SUB and the side surface of the opening portion OP1 is 54.7 degrees.

In this etching process, an inexpensive processing method is employed without using a liquid immersion technique using ArF lasers. Instead of TMAH, the above-described etch treatment may be performed using alkaline solutions such as potassium hydroxide (KOH) or sodium hydroxide (NaOH). However, TMAH is commonly used as a developer, for example, when forming a resist pattern. Therefore, it is possible to easily use TMAH in the manufacturing process of the semiconductor device in terms of managing the solution after the etching process. Therefore, it is preferable to use etching solutions containing TMAH for the etching process.

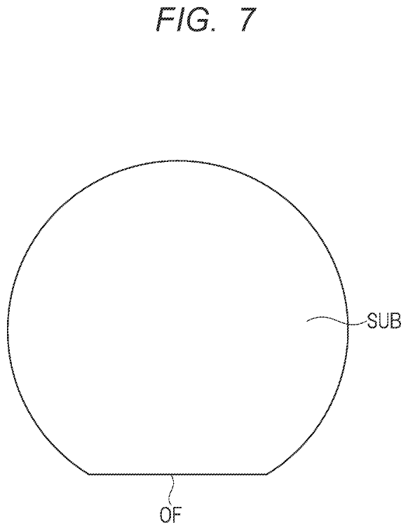

Hereinafter, a method of manufacturing the semiconductor device 100 according to the first embodiment will be described with reference to FIGS. 7 to 14. Hereinafter, the region 1A and the area 2A shown in FIG. 5 will be mainly described.

Briefly describing the outline of the respective manufacturing processes, first, to prepare a semiconductor-substrate SUB having an n-type drift-region NV. Next, a IGBT is formed in the region 1A, and a diode is formed in the region 2A. Thereafter, the thickness of the semiconductor substrate SUB in the region 1A is made thinner than the thickness of the semiconductor substrate SUB in the region 2A.

As shown in FIG. 7, an orientation flat OF is provided on the wafer-state semiconductor-substrate SUB. In the first embodiment, the orientation flat OF is machined along the <110> direction.

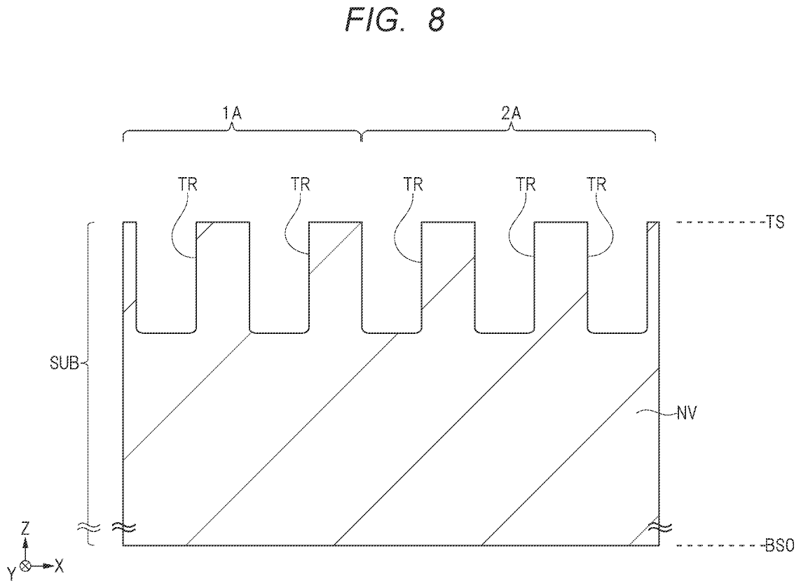

As shown in FIG. 8, in the semiconductor substrate SUB on the front-face TS, the regions 1A and 2A of the semiconductor substrate are formed with trench TR. First, an insulating film made of, for example, a silicon oxide film is formed on a semiconductor-substrate SUB, and the insulating film is patterned by a photolithography method and a dry etching process to form a hard mask. Next, an anisotropic etch process is performed on the semiconductor substrate SUB using the hard mask as a mask to form a trench TR in the semiconductor substrate SUB. Thereafter, above hardmask is removed by wet etching or the like.

Note that the thickness of the semiconductor substrate SUB at this point is thicker than in FIG. 5, the back surface of the semiconductor substrate SUB is shown as the back surface BS0. The thickness from the front TS to the back surface BS0 is about 700 to 800 micrometers. By the polishing step described later, the thickness of the semiconductor-substrate SUB is reduced, and the back surface BS0 becomes the back surface BS.

Further, although not illustrated here, prior to forming the trench TR, the field insulating film FI illustrated in FIG. 4 is formed on the front surface TS of the semiconductor-substrate SUB in the outer peripheral region 3A by, for example, thermal oxidation.

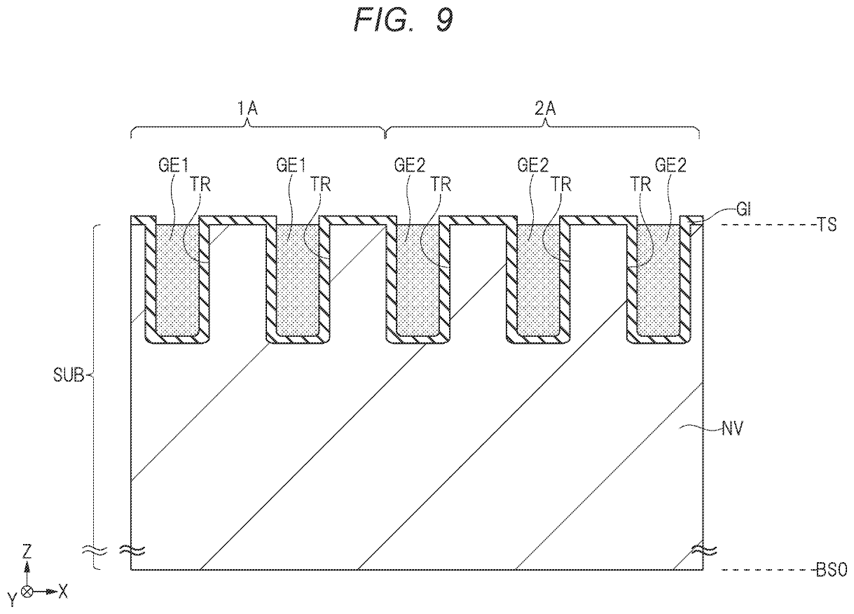

As shown in FIG. 9, a gate insulating film GI is formed inside the trench TR and on the front surface TS of the semiconductor-substrate SUB by a thermal oxidization method. Next, an n-type doped polycrystalline silicon film is formed on the gate insulating film GI by, for example, a CVD method so as to fill the trench TR. Next, the polycrystalline silicon film formed outside the trench TR is removed by dry-etching. The polycrystalline silicon film formed in the trench TR of the region 1A is left as the gate electrode GE1, and the polycrystalline silicon film formed in the trench TR of the region 2A is left as the gate electrode GE2. Although not shown here, in the step of forming the gate electrode GE1, GE2, the gate lead-out portion GE1a, GE2a shown in FIG. 2 is also formed.

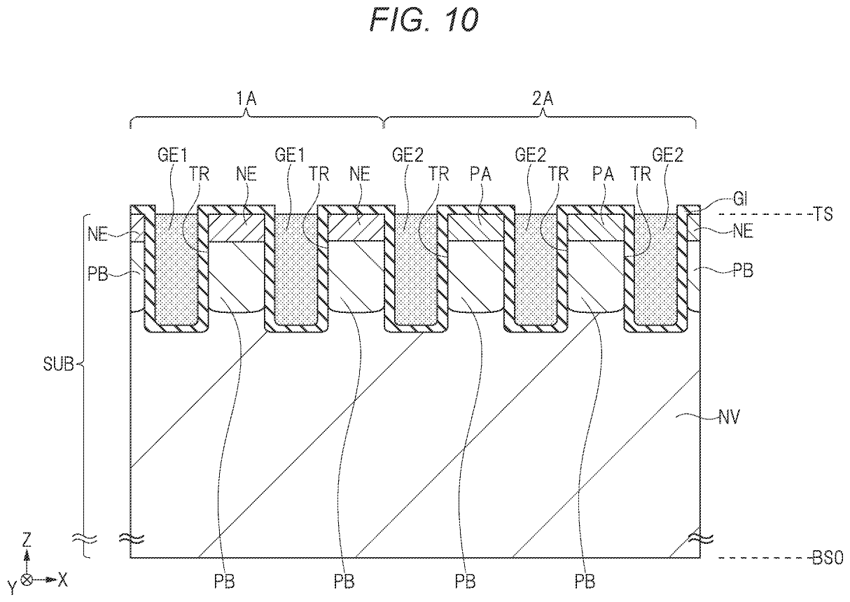

As shown in FIG. 10, on the semiconductor substrate SUB on the front TS of the semiconductor substrate 1A and the region 2A, a p-type base region PB is formed by photolithography and ion-implantation. The base-region PB is formed to be shallower than the bottom of the trench TR. Although not shown here, the p-type well region PW shown in FIG. 4 is formed by a photolithography method and an ion-implantation method before or after the base region PB is formed.

Next, on the front TS of SUB, an n-type emitter region NE is formed in the base region PB of the region 1A by photolithography and ion-implantation, and a p-type anode region PA is formed in the base region PB of the region 2A. Note that, although not shown here, the p-type high-concentration diffused region PR shown in FIG. 4 is formed by photolithography and ion-implantation before or after the emitter region NE and the anode region PA are formed. Thereafter, for example, heat treatment is performed at 950° C. for 30 seconds to activate impurities contained in the impurity regions.

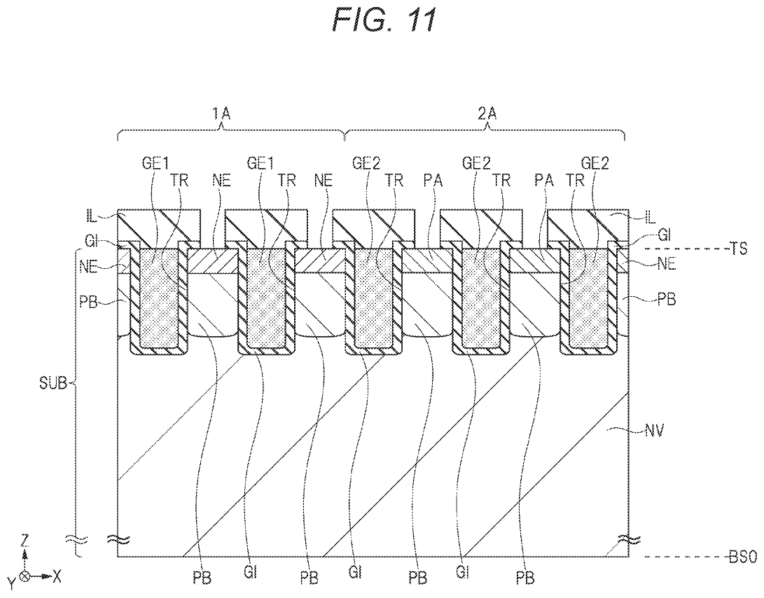

As shown in FIG. 11, in the region 1A and the region 2A, the interlayer insulating film IL is formed on the front surface TS of the semiconductor-substrate SUB by, for example, CVD method. Next, a contact hole reaching the emitter region NE and the anode region PA is formed in the interlayer insulating film IL by a photolithography method and a dry etching process. Although not shown here, the contact holes are also formed on the high-concentration diffused regions PR and the gate-lead-out portions GE1a, GE2a.

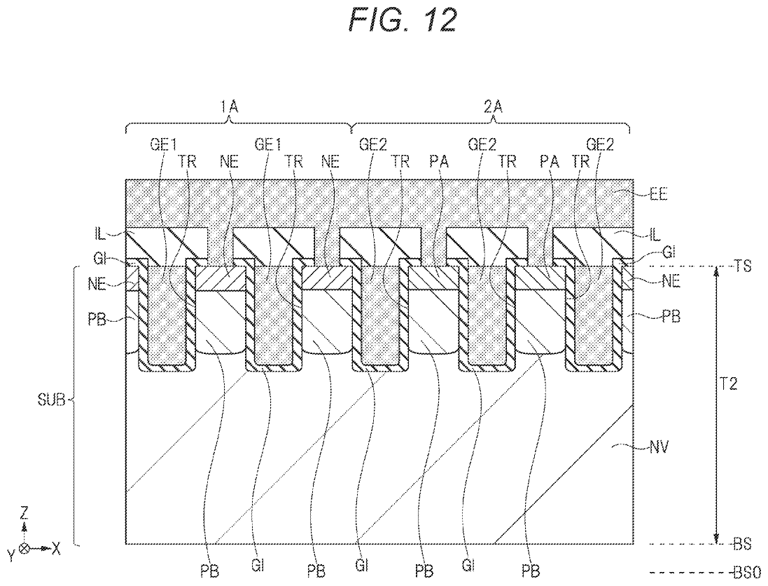

As shown in FIG. 12, the emitter-electrode EE is formed on the interlayer insulating film IL so as to fill the inside of the contact hole. First, a titanium nitride film and an aluminum film are sequentially formed on the interlayer insulating film IL by, for example, a sputtering method. Next, the emitter-electrode EE is formed by patterning the titanium nitride film and the aluminum film. Note that the gate-wiring GW is also formed on the interlayer insulating film IL by the same process as the process of forming the emitter-electrode EE.

Through this process, the gate electrode GE1 is electrically connected to the gate line GW, and the emitter region NE, the anode region PA, the base region PB, the high-concentration diffused region PR, and the gate electrode GE2 are electrically connected to the emitter electrode EE.

Next, in the region 1A and the region 2A, the thickness of the semiconductor substrate SUB is reduced by polishing the back surface BS0 of the semiconductor substrate SUB. In FIG. 12, the back surface of the semiconductor-substrate SUB after the polishing step is illustrated as a back surface BS. This polishing step allows the thickness of the semiconductor-substrate SUB to be in a thickness T2 that is optimal for the properties of the diode. The thickness T2 is, for example, 50 to 160 μm, more preferably 85 μm.

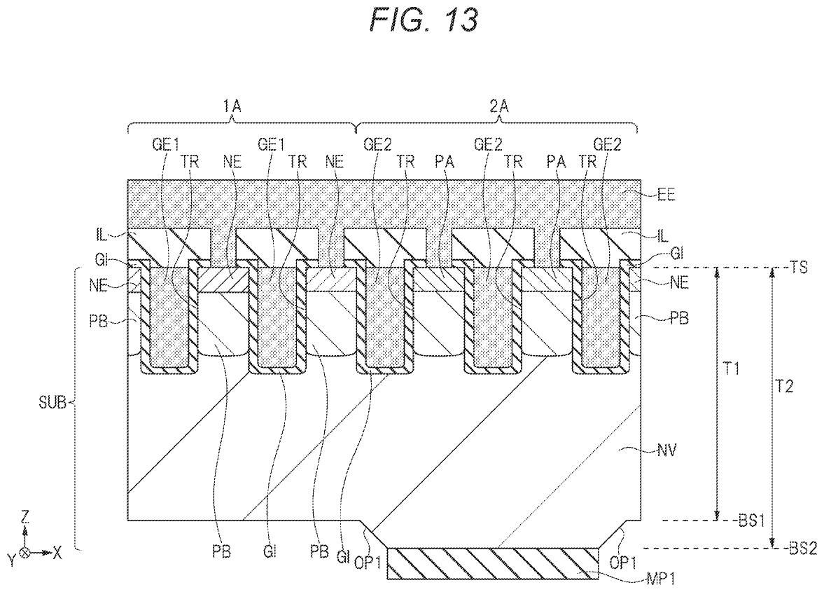

As shown in FIG. 13, by forming the opening OP1 on the back surface BS of the semiconductor substrate SUB, the thickness BS1 of the semiconductor substrate SUB in the region 1A is made thinner than the thickness BS2 of the semiconductor substrate SUB in the region 2A. First, a mask pattern MP1 is formed to open the back surface BS of the region 1A on the semiconductor substrate SUB and to selectively cover the back surface BS of the region 2A on the semiconductor substrate SUB. The mask pattern MP1 is formed of, for example, a resist pattern or an insulating film such as a silicon oxide film patterned using a resist pattern.

Next, using the mask pattern MP1 as a mask, an etching process using an etching solution containing TMAH is performed to form an opening OP1 on the back surface BS of the region 1A on SUB of the semiconductor substrate. As a result, a step is generated on the back surface SUB of the semiconductor substrate 1A so that the back surface BS1 of the semiconductor substrate SUB in the region 2A is positioned above the back surface BS2 of the semiconductor substrate. Next, the mask pattern MP1 is removed by an asking process, a wet etch process, or the like. As shown in FIG. 3, in Embodiment 1, the shape of the opening portion OP1 is a rectangular shape in which a side along the Y direction is a long side and a side along the X direction is a short side.

The mask pattern MP1 is formed so as to also cover the back surface BS of the semiconductor-substrate SUB in the outer peripheral region 3A. Therefore, after the etching process using the etching solutions containing TMAH, the thickness of the semiconductor substrate SUB in the region 1A is thinner than the thickness of the semiconductor substrate SUB in the outer peripheral region 3A.

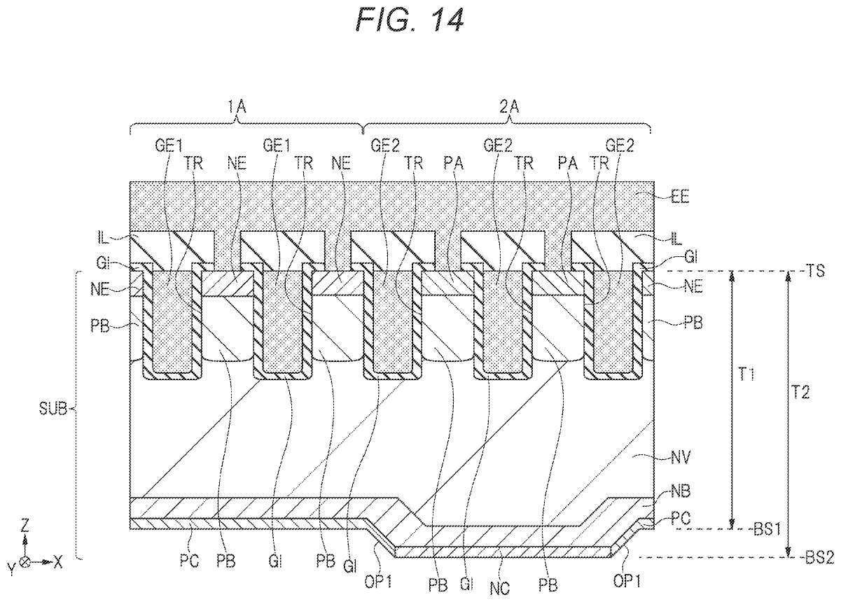

As shown in FIG. 14, a buffer region NB, a collector region PC, and a cathode region NC are sequentially formed on the back surface BS of SUB. First, on the semiconductor substrate SUB on the back surface BS of the semiconductor substrate 1A and the region 2A, an n-type buffer region NB is formed by an ion-implantation method. Next, on the back surface SUB of the semiconductor substrate BS, a p-type collector region 1A is formed on the semiconductor substrate SUB of the region PC by photolithography and ion-implantation, and an n-type cathode region NC is formed on the semiconductor substrate 2A. The buffer region NB and the n-type cathode region NC are also formed in the semiconductor-substrate SUB in the outer peripheral region 3A.

Next, by forming the collector-electrode CE, the structure shown in FIG. 5 is obtained. In the regions 1A and 2A, the collector-electrode CE is formed on the back BS1, BS2 of the semiconductor-substrate SUB by, for example, a sputtering method. By this process, the collector region PC and the cathode region NC are electrically connected to the collector electrode CE.

Thereafter, a dicing process or the like is performed on the semiconductor substrate SUB in the wafer condition, whereby the semiconductor substrate SUB is singulated, and a plurality of semiconductor devices 100 that are semiconductor chips are obtained.

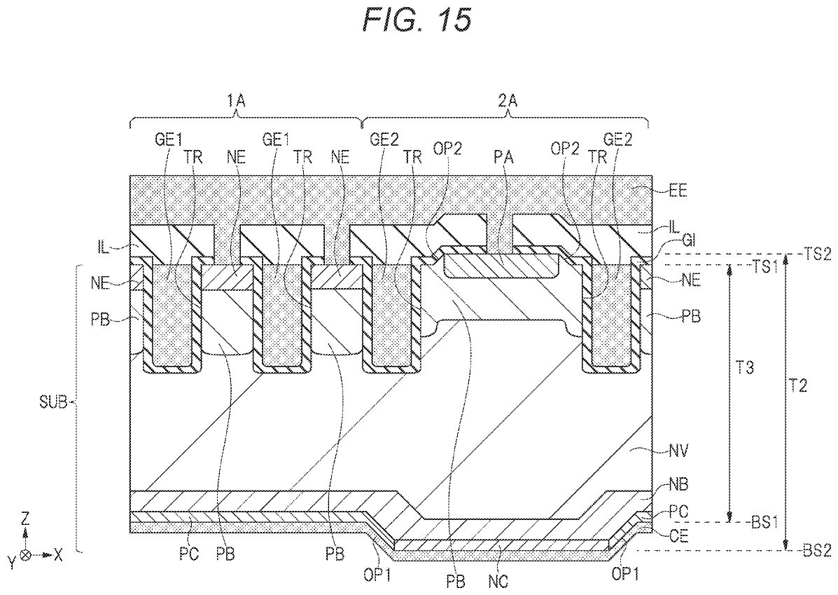

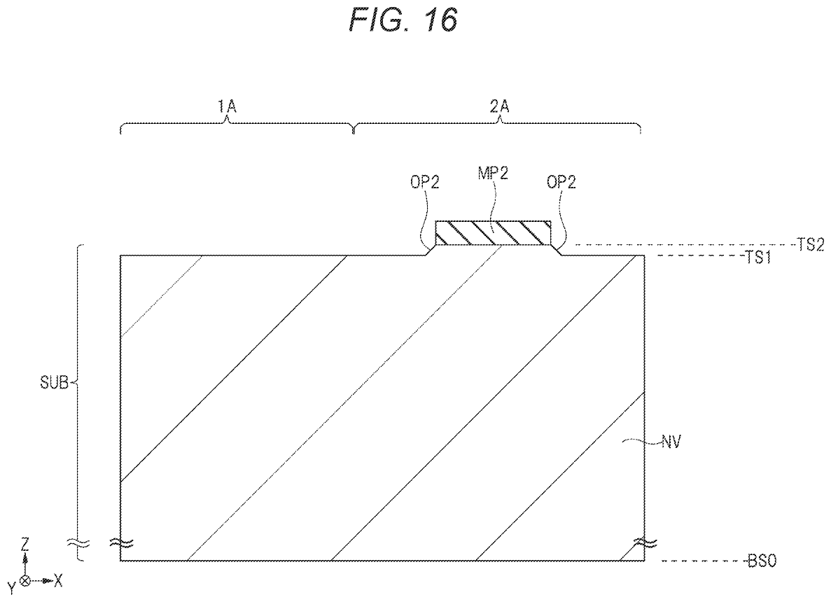

(Embodiment 2) will be described with reference to FIGS. 15 and 16 below, the semiconductor device 100 in the second embodiment. Note that, in the following, differences from the first embodiment will be mainly described, and descriptions of points that overlap with the first embodiment will be omitted. As shown in FIG. 15, in the second embodiment, similarly to the first embodiment, the thickness T3 of the semiconductor substrate SUB in the region 1A is smaller than the thickness T2 of the semiconductor substrate SUB in the region 2A. However, in the second embodiment, the opening portion OP2 is formed on the front surface TS of the region 1A on the semiconductor-substrate SUB. Therefore, so that the surface TS1 of the semiconductor substrate SUB of the region 1A is located below the surface TS2 of the semiconductor substrate SUB of the region 2A, a step is generated on the surface TS of the semiconductor substrate SUB.

Therefore, since the thickness 1A of the region T3 is thinner than the thickness T1 of the first embodiment, the distance between the region 1A and the region PB to the region PC is shorter than that of the first embodiment. In other words, the thickness of the drift-region NV of the region 1A is thinner than that of the first embodiment. As a result, the on-resistance of IGBT can be further reduced while the performance of the diode is maintained at the same level as that of the first embodiment.

On the other hand, the thickness T3 of the region 1A may be designed to be the same as the thickness T1 of the first embodiment. Then, the thickness T2 of the region 2A is larger than the thickness T2 of the first embodiment. Then, the distance between the base region PB of the region 2A and the cathode region NC of the region 2A is longer than that of the first embodiment. In other words, the thickness of the drift-region NV of the region 2A is larger than that of the first embodiment. Therefore, it is possible to further suppress the possibility of ringing occurring in the diode while maintaining the performance of IGBT at the same level as in the first embodiment.

The thickness 1A of the semiconductor substrate SUB in the region T1 is the thickness from the front surface TS1 of the semiconductor substrate SUB to the back surface BS1 of the semiconductor substrate SUB. The thickness 2A of the semiconductor substrate SUB in the region T3 is the thickness of the semiconductor substrate SUB from the front surface TS2 to the back surface BS2 of the semiconductor substrate SUB. The thickness T1 is thinner within 100˜300 nm than the thickness T3.

In the semiconductor substrate SUB, on the front TS side, the trench TR is formed and the depth of the ion-implantation is adjusted, so that the accuracy of the photolithography is required more than the back surface BS side of the semiconductor substrate SUB. Therefore, if the front surface TS1 of the semiconductor-substrate SUB in the region 1A is excessively retracted, the resolution of photolithography may vary. Therefore, it is preferable that the depth of the opening portion OP2 is shallower than the depth of the opening portion OP1.

FIG. 16 illustrates a manufacturing process for forming the opening OP2 according to the second embodiment. The manufacturing step of FIG. 16 is performed prior to the step of forming the trench TR of FIG. 8.

First, a mask pattern MP2 is formed to open the surface TS of the region 1A on the semiconductor substrate SUB and to selectively cover the surface TS of the region 2A on the semiconductor substrate SUB. The mask pattern MP2 is formed of, for example, a resist pattern or an insulating film such as a silicon oxide film patterned using a resist pattern. Next, using the mask pattern MP2 as a mask, an etching process using an etching solution containing TMAH is performed to form an opening OP2 on the front surface TS of the semiconductor substrate SUB of the region 1A. Thereafter, the mask pattern MP2 is removed by an asking process, a wet etch process, or the like.

Subsequent manufacturing steps are the same as those in FIG. 8 and thereafter.

Here, although an example has been described in which the opening SUB is provided on the back surface BS of the semiconductor substrate OP1 and the opening TS of the semiconductor substrate is provided with the opening OP2, the opening OP1 may not be provided, but only the opening OP2 may be provided. Even in this case, ringing can be suppressed in the region 2A and the on-resistance can be reduced in the region 1A as compared with the related art.

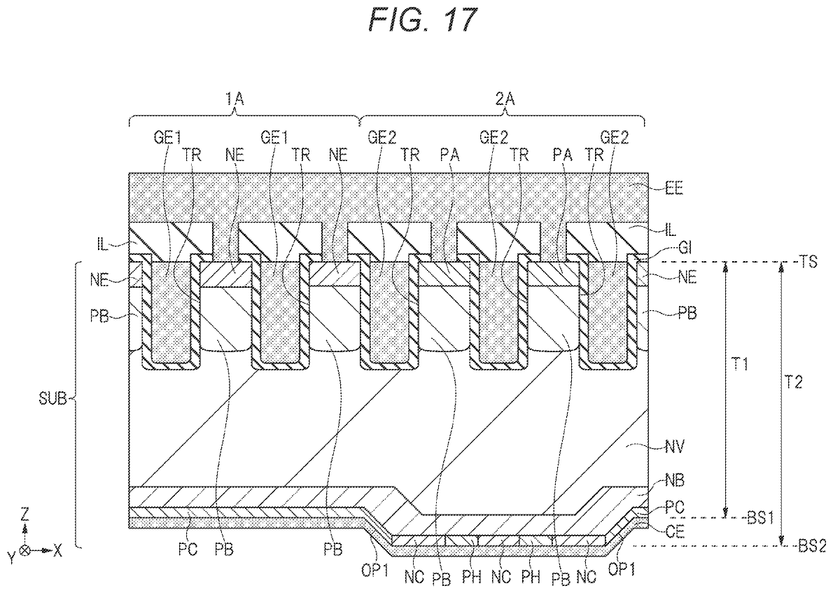

(Embodiment 3) will be described with reference to FIG. 17 below, the semiconductor device 100 in the third embodiment. Note that, in the following, differences from the first embodiment will be mainly described, and descriptions of points that overlap with the first embodiment will be omitted.

In the first embodiment, an n-type cathode region NC is formed on the entire back surface BS2 of the region 2A on the semiconductor-substrate SUB. As shown in FIG. 17, in the third embodiment, on the back surface BS2 of the semiconductor substrate SUB, not only the cathode region NC but also a p-type hole-injection region (semiconductor region) PH is formed on the semiconductor substrate SUB of the region 2A. The hole-injection region PH is formed so as to replace a part of the cathode region NC, and is in contact with the cathode region NC. The impurity concentration of the hole injection regions PH is 1×10¹⁷˜1×10²¹ cm⁻³.

The portion where the diode is turned on mainly extends from directly above the cathode region NC to the anode region PA. The on-operation is basically not performed immediately above the hole injection region PH because the carrier density immediately above the hole injection region PH is lower than the carrier density immediately above the cathode region NC.

When a reverse bias is applied to the diode (recovery operation), holes are discharged to the anode region PA side, and electronics are discharged to the cathode region NC side. Since a part of the cathode region NC is set to the hole injection region PH, the carrier density at the time of the on-operation partially differs, the depletion layer spreads directly above the cathode region NC and directly above the hole injection region PH.

Some of the electrons discharged during the recovery operation do not pass through the hole-injection region PH and flow toward the cathode region NC. At this time, IR-Drop is generated by the electronic current and the resistive components of the buffer regions NB. Since the hole-injection region PH is in contact with the cathode region NC, when IR-Drop exceeds 0.7V (built-in voltage), PN junction is transiently turned on. Consequently, holes are injected from the hole injection region PH, and a plasma region is formed in the vicinity of the cathode region NC. Since the depletion layer stops spreading in the plasma region, the electric field is relaxed on the back surface BS2 of the semiconductor-substrate SUB, and the occurrence of ringing is easily suppressed. In other words, the reliability of the semiconductor device can be further improved by the hole-injection-region PH.

Note that such a hole-injection region PH can be formed after forming the buffer region NB in FIG. 14. That is, on the semiconductor substrate SUB on the back BS2 of the semiconductor substrate 2A, a p-type hole implantation region PH is formed by photolithography and ion-implantation. The order in which the hole-injection region PH, the cathode region NC, and the collector region PC are formed may be performed first.

Further, the technique disclosed in the third embodiment can be used in combination with the technology disclosed in the second embodiment as appropriate.

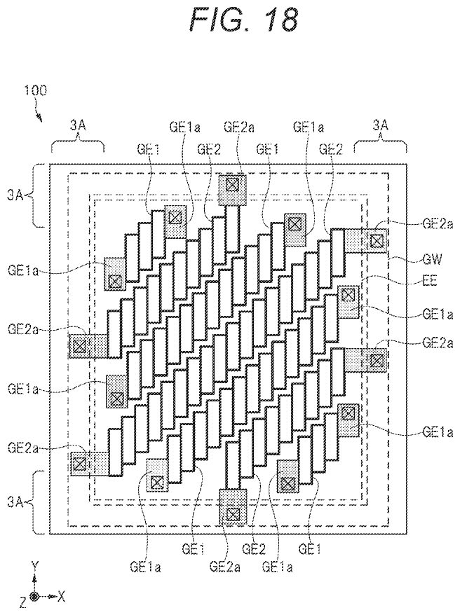

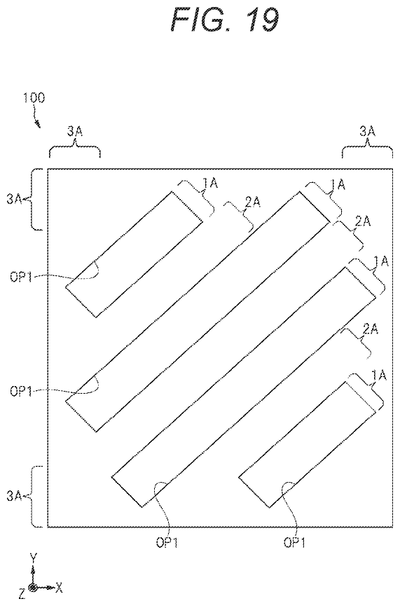

(Embodiment 4) will be described with reference to FIGS. 18 and 19 below, the semiconductor device 100 in the fourth embodiment. Note that, in the following, differences from the first embodiment will be mainly described, and descriptions of points that overlap with the first embodiment will be omitted. FIG. 18 shows a configuration mainly in the vicinity of the front TS of the semiconductor-substrate SUB. FIG. 19 illustrates a back surface BS of the semiconductor-substrate SUB.

In the first embodiment, the wafer-state semiconductor substrate SUB shown in FIG. 7 is provided with an orientation flat OF processed along the <110> direction. In the fourth embodiment, an orientation flat OF processed along the <100> direction is provided on the wafer-state semiconductor substrate SUB.

When an opening OP1 is formed on such a SUB by an etching process using an etching solution containing TMAH, the crystalline surface on the side surface of the opening OP1 does not form the (111) plane when the opening is processed into the form shown in FIG. 3. Therefore, in the fourth embodiment, the mask pattern MP1 for forming the opening OP1 needs to be rotated by 45 degrees.

As shown in FIG. 19, the shape of the opening OP1 in Embodiment 4 is a rectangular shape in which a side along a direction (third direction) inclined by 45 degrees from the Y direction is a long side, and a side along a direction (fourth direction) inclined by 90 degrees from the third direction is a short side.

Accordingly, the layout of the trenches TR, the gate-electrode GE1, GE2, and the like formed in the region 1A and the region 2A also needs to be changed so as to be inclined by 45 degrees. In the first embodiment, the trench TR is formed in a stripe-like shape extending in the Y direction, but in the fourth embodiment, a plurality of trench TR formed in a rectangular shape are arranged in the third direction. That is, each of the plurality of trenches TR has a rectangular shape having a first portion extending in the Y direction and a second portion extending in the X direction. The plurality of trench TR are connected to each other along the third direction. Note that the gate-electrode GE1, GE2 is embedded in the rectangular trench TR in the same manner as in the first embodiment.

As described above, even when the orientation flat OF machined along the <100> direction is provided in the semiconductor-substrate SUB, the diode of IGBT of the region 1A and the region 2A can be formed in accordance with the shape of the opening OP1, and the ringing can be suppressed and the on-resistance can be reduced in the region 1A in the region 2A.

Further, the technology disclosed in the fourth embodiment can be appropriately combined with the technology disclosed in the second embodiment and the third embodiment.

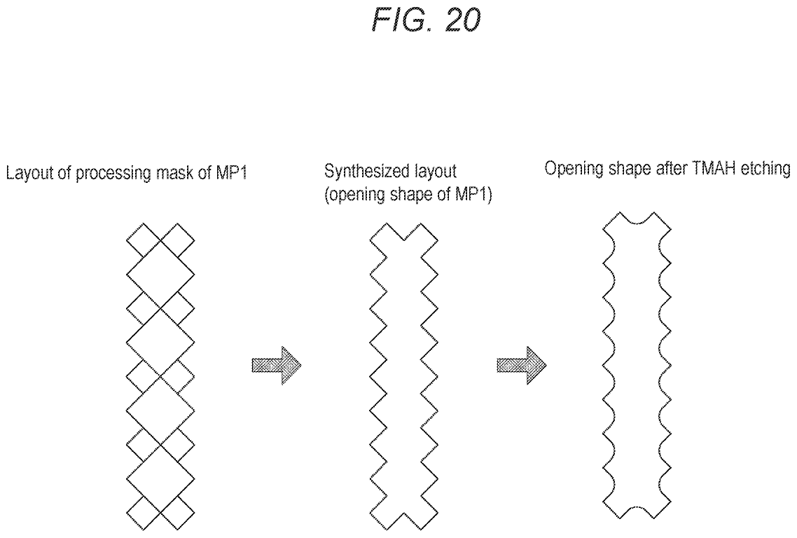

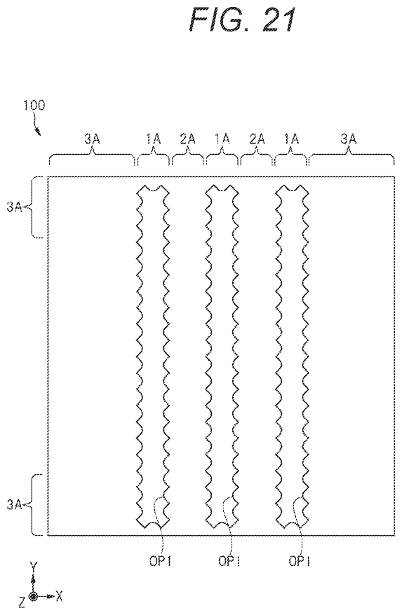

(Embodiment 5) will be described with reference to FIGS. 20 and 21 below, the semiconductor device 100 in the fifth embodiment. Note that, in the following, differences from the fourth embodiment will be mainly described, and descriptions of points overlapping with the fourth embodiment will be omitted.

In the fifth embodiment, as in the fourth embodiment, the orientation flat OF processed along the <100> direction is provided on the wafer-state semiconductor substrate SUB. Therefore, the mask pattern MP1 for forming the opening OP1 needs to be rotated by 45 degrees. However, in the fifth embodiment, the trenches TR and the gate-electrode GE1, GE2 formed in the regions 1A and 2A are the same as those in FIG. 2.

In the fifth embodiment, the opening shapes of the mask pattern MP1 are devised. As shown in FIG. 20, a plurality of squares each including a side along the third direction and a side along the fourth direction are prepared as the layout of the processing mask of the mask pattern MP1. Then, they are synthesized so as to extend in the Y direction as a whole. A mask pattern MP1 is formed using such a processing mask.

That is, the opening shape of the mask pattern MP1 is a shape in which a plurality of quadrangles formed by the side along the third direction and the side along the fourth direction are joined so as to extend in the Y direction as a whole. By etching the back surface BS of the semiconductor substrate SUB using the mask pattern MP1 as a mask, as shown in FIG. 21, an opening OP1 extending in the Y-direction as a whole is formed.

Although the opening of the mask pattern MP1 has a right-angled shape such as the connecting portion of the quadrangle, when an etching process using an etching solution containing TMAH is performed, such a portion is easily rounded.

As described above, even when the orientation flat OF processed along the <100> direction is provided in the semiconductor-substrate SUB, the same layout as in FIG. 2 can be performed.

Further, the technique disclosed in the fifth embodiment can be appropriately combined with the technology disclosed in the second embodiment and the third embodiment.

Although the present invention has been described in detail based on the embodiments, the present invention is not limited to these embodiments and can be variously modified without departing from the gist thereof.

What is claimed is:

1. A semiconductor device including a first region and a second region, comprising:
a semiconductor substrate of a first conductivity type having a front surface and a back surface;
a IGBT formed on the semiconductor substrate of the first region; and
a diode formed on the semiconductor substrate of the second region,
wherein a thickness of the semiconductor substrate of the first region is thinner than a thickness of the semiconductor substrate of the second region.

2. A semiconductor device according to claim 1, wherein a step is formed on the back surface of the semiconductor substrate so that the back surface of the semiconductor substrate in the first region is positioned above the back surface of the semiconductor substrate in the second region.

3. A semiconductor device according to claim 2, wherein a step is formed on the surface of the semiconductor substrate so that the surface of the semiconductor substrate in the first region is located below the surface of the semiconductor substrate in the second region.

4. A semiconductor device according to claim 1, further comprising;
a base region of a second conductivity type opposite to the first conductivity type formed on the semiconductor substrate of the first region;
an emitter region of the first conductivity type formed in the base region;
a trench formed on the semiconductor substrate in the first region so that a bottom portion thereof is positioned below the base region;
a gate insulating film formed inside the trench;
a gate electrode formed on the gate insulating film so as to fill the inside of the trench;
a collector region of the second conductivity type formed on the back surface side of the semiconductor substrate;
an anode region of the second conductivity type formed on the semiconductor substrate at the front surface side in the second region;
a cathode region of the first conductivity type formed on the semiconductor substrate at the back surface side in the second region;
an interlayer insulating film formed on the front surface of the semiconductor substrate in the first region and the second region;
an emitter electrode and a gate wiring formed on the interlayer insulating film; and
a collector electrode formed on the back surface of the semiconductor substrate in the first region and the second region,
wherein the gate electrode is electrically connected to the gate wiring,
wherein the base region, the emitter region and the anode region are electrically connected to the emitter electrode, and wherein the collector region and the cathode region are electrically connected to the collector electrode.

5. A semiconductor device according to claim 4, further comprising a hole injection region of the second conductivity type,
wherein the hole injection region is formed in the semiconductor substrate of the second region at the back surface side so as to be in contact with the cathode region.

6. A semiconductor device according to claim 4, further comprising an outer peripheral region surrounding the first region and the second region in a plan view,
wherein the cathode region is also formed on the semiconductor substrate in the outer peripheral region at the back surface side, and
wherein a thickness of the semiconductor substrate in the first region is thinner than a thickness of the semiconductor substrate in the outer peripheral region.

7. A semiconductor device according to claim 4, wherein the base region is also formed on the semiconductor substrate of the second region,
wherein the anode region is formed on the base region of the second region, and
wherein a distance between the base region of the first region and the collector region of the first region is shorter than a distance between the base region of the second region and the cathode region of the second region.

8. A semiconductor device according to claim 1, wherein a thickness of the semiconductor substrate in the first region is thinner than a thickness of the semiconductor substrate in the second region within a range of 1 μm or more and 10 μm or less.

9. A method of manufacturing a semiconductor device including a first region and a second region, the method comprising the steps of:
(a) providing a semiconductor substrate of a first conductivity type having a front surface and a back surface;
(b) forming a IGBT on the semiconductor substrate of the first region and forming a diode on the semiconductor substrate of the second region; and
(c) making a thickness of the semiconductor substrate of the first region thinner than a thickness of the semiconductor substrate of the second region.

10. A method of manufacturing a semiconductor device according to claim 9, the step (b) further comprising:
(b1) a step of forming a trench in the semiconductor substrate of the first region at the surface side;
(b2) a step of forming a gate insulating film inside the trench;
(b3) a step of forming a gate electrode on the gate insulating film so as to fill the inside of the trench;
(b4) a step of forming a base region of a second conductivity type which is opposite to the first conductivity type, on the surface side of the semiconductor substrate so as to be shallower than the bottom of the trench;
(b5) a step of forming an emitter region of the first conductivity type in the base region;
(b6) fa step of forming an anode region of the second conductivity type on the surface side of the semiconductor substrate;
(b7) a step of forming an interlayer insulating film on the surface of the semiconductor substrate in the first region and the second region;
(b8) a step of forming an emitter electrode on the interlayer insulating film so as to be electrically connected to the base region, the emitter region and the anode region, and forming a gate wiring on the interlayer insulating film so as to be electrically connected to the gate electrode;
(b9) a step of forming a collector region of the second conductivity type on the back surface side of the semiconductor substrate in the first region;
(b10) a step of forming a cathode region of the first conductivity type on the semiconductor substrate in the second region; and
(b11) a step of forming a collector electrode on the back surface side of the semiconductor substrate in the first region and the second region, so as to be electrically connected to the collector region and the cathode region.

11. A method of manufacturing a semiconductor device according to claim 10, wherein the step (c) is performed after the steps (b1) to (b8) and before the steps (b9) to (b11), and the step (c) further including:
(c1) a step of forming a first mask pattern that opens the back surface of the semiconductor substrate in the first region and selectively covers the back surface of the semiconductor substrate in the second region;
(c2) after the step (c1), a step of forming a first opening on the back surface of the semiconductor substrate in the first region by performing an etching process using an etching solution containing tetramethylammonium hydroxide using the first mask pattern as a mask; and
(c3) a step of removing the first mask pattern after the step (c2).

12. A method of manufacturing a semiconductor device according to claim 11, wherein the step (c) is performed after the step (b8) and before the steps (c1), and wherein the step (c) further includes the step (c0) of polishing the back surface of the semiconductor substrate in the first region and the second region to thin a thickness of the semiconductor substrate.

13. A method of manufacturing a semiconductor device according to claim 11, wherein the step (c) is performed after the step (a) and before the steps (b1)˜(b11), and wherein the step (c) further includes:
(c4) a step of forming a second mask pattern that opens the surface of the semiconductor substrate in the first region and selectively covers the surface of the semiconductor substrate in the second region;
(c5) a step of forming a second opening on the surface of the semiconductor substrate in the first region by performing an etching process using an etching solution containing tetramethylammonium hydroxide using the second mask pattern as a mask after the step (c4); and
(c6) a step of removing the second mask pattern after the step (c5).

14. A method of manufacturing a semiconductor device according to claim 11, wherein the semiconductor substrate prepared in step (a) is provided with an orientation flat processed along a <110> direction,
wherein the trench includes a plurality of trenches in the semiconductor substrates of the first region,
wherein each of the plurality of trenches extends in a first direction in a plan view and is adjacent to each other in a first direction orthogonal to the second direction in a plan view, and
wherein a shape of the first opening portion is a rectangular shape in which a side along the first direction is a long side and a side along the second direction is a short side.

15. A method of manufacturing a semiconductor device according to claim 11, wherein the semiconductor substrate prepared in step (a) is provided with an orientation flat processed along a <110> direction,
wherein the trench includes a plurality of trenches in the semiconductor substrates of the first region,
wherein each of the plurality of trenches has a rectangular shape including a first portion extending in a first direction in a plan view, and a second portion extending in a second direction perpendicular to the first direction in a plan view,
wherein the plurality of trenches are connected one another along a third direction inclined 45 degrees from the first direction, and
wherein a shape of the first opening is a rectangular shape having a long side along the third direction and having a short side along a fourth direction inclined 90 degrees from the third direction,

16. A method of manufacturing a semiconductor device according to claim 11, wherein the semiconductor substrate prepared in step (a) is provided with an orientation flat processed along a <110> direction,
wherein the trench includes a plurality of trenches in the semiconductor substrates of the first region,
wherein each of the plurality of trenches extends in a first direction in a plan view and is adjacent to each other in a first direction orthogonal to the second direction in a plan view, and
wherein an opening shape of the first mask pattern is a quadrangle formed by a side along a third direction inclined by 45 degrees from the first direction and a side along a forth direction inclined by 90 degrees from the third direction and is formed so as to extend in the first direction as a whole.

17. A method of manufacturing a semiconductor device according to claim 10, wherein the step (b) is performed after the step (b8) and prior to the step (b11),
wherein the step (b) further includes a step of (b12) forming a hole-injection region of the second conductivity type on the semiconductor substrate of the second region on at the back surface side so as to be in contact with the cathode region.

18. A method of manufacturing a semiconductor device according to claim 10, wherein the semiconductor substrate further includes an outer peripheral region surrounding the first region and the second region in a plan view,
wherein the cathode region is also formed on the semiconductor substrate in the outer peripheral region at the back surface side in the step (b10), and
wherein a thickness of the semiconductor substrate in the first region is thinner than a thickness of the semiconductor substrate in the outer peripheral region in the step (c).

19. A method of manufacturing a semiconductor device according to claim 10, wherein in the (b4) step, the base region is also formed on the semiconductor substrate of the second region,
wherein in the (b6) step, the anode region is formed in the base region of the second region,
wherein a distance between the base region of the first region and the collector region of the first region is shorter than a distance between the base region of the second region and the cathode region of the second region.

20. A method of manufacturing a semiconductor device according to claim 9, wherein after the step ©, a thickness of the semiconductor substrate in the first region is thinner in a range of 1 μm or more and 10 μm or less than a thickness of the semiconductor substrate in the second region.
